(19) United States
(12) Patent Application Publication
(10) Pub. No.: US 2025/0357202 A1
(43) Pub. Date: Nov. 20, 2025

(54) SEMICONDUCTOR PACKAGE REDISTRIBUTION STRUCTURE AND FABRICATION METHOD THEREOF

(71) Applicant: Taiwan Semiconductor Manufacturing Company, Ltd., Hsin-Chu (TW)

(72) Inventors: Dian-Hau CHEN, Hsinchu (TW); Chen-Chiu HUANG, Taichung City (TW); Hsiang-Ku SHEN, Hsinchu City (TW); ShuFang CHEN, Hsinchu (TW); Ying-Yao LAI, Taichung City (TW); Wen-Ling CHANG, Miaoli County (TW); Chi-Feng LIN, Hsinchu City (TW); Peng-Chung JANGJIAN, Hsinchu (TW); Jo-Lin LAN, Kaohsiung City (TW); Fang-I Chih, Tainan City (TW); Ching-Wei Lin, Hsinchu City (TW)

(21) Appl. No.: 19/285,675

(22) Filed: Jul. 30, 2025

Related U.S. Application Data
(63) Continuation of application No. 18/358,662, filed on Jul. 25, 2023.
(60) Provisional application No. 63/486,066, filed on Feb. 21, 2023.

(51) Int. Cl. H01L 21/768; H01L 21/02; H01L 23/522

(52) U.S. Cl. CPC H01L 21/76873; H01L 21/02112; H01L 21/76843; H01L 23/5226

(57) ABSTRACT

A semiconductor device includes an interconnect structure over a substrate and a redistribution layer over the interconnect structure. The redistribution layer includes a first via, a first metal line disposed on the first via, a second via, and a second metal line disposed on the second via. A width of the first metal line is greater than a width of the second metal line. A thickness of the first metal line is equal to a thickness of the second metal line. Each of the first and second metal lines includes a top portion having a conductive material of a first grain size and a bottom portion having the conductive material of a second grain size. The first grain size is greater than the second grain size.

### PRIORITY DATA

This is a continuation application of U.S. patent application Ser. No. 18/358,662, filed Jul. 25, 2023, which claims benefit of U.S. Provisional Patent Application No. 63/486,066, filed Feb. 21, 2023, each of which is incorporated herein by reference in its entirety.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

With the increasing demand for smaller and more innovative packaging techniques in semiconductor devices, advanced packaging technologies such as Package-on-Package (PoP) and Chip-On-Wafer-On-Substrate (CoWoS) have emerged to provide higher integration and component density. One technology that has gained significant popularity, especially when combined with Wafer Level Packaging (WLP), is Integrated Fan Out (InFO) package technology. InFO packages offer a compact solution with high functional density, low cost, and superior performance. In the InFO packages, formation of redistribution layers (RDLs) plays an important role during packaging process. For example, the RDLs can provide redistributed access to I/O connectors of semiconductor dies. The RDLs may be formed by plating copper on a copper seed layer. Although existing electroplating processes have been generally adequate for their intended purposes, they have not been entirely satisfactory in all respects. For example, existing techniques may cause uneven heights in metal lines of different widths due to loading effects during copper deposition. As a consequence, the subsequently formed vias intended to connect with these uneven metal lines end up having differing lengths. These concerns may have a detrimental impact on the mechanical and electrical reliability of the RDLs. Consequently, there is an increasing demand for an electroplating process that effectively tackles these limitations.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A, 1B, 1C, 1D, 1E, and 1F are schematic cross-sectional views at intermediate stages of forming a redistribution layer in accordance with some embodiments.

FIG. 2 is a diagram illustrating a relationship between metal line heights and metal line widths in accordance with some embodiments.

FIG. 3 is a schematic cross-sectional view of electroplating apparatus for performing an electroplating process in accordance with some embodiments.

FIG. 4 is a diagram illustrating a multi-step process of applying plating current versus time at different stages of electroplating in accordance with some embodiments.

FIG. 5 is a process flow for forming a redistribution layer in accordance with some embodiments.

FIGS. 6, 7, 8, 9, 10, 11, 12, 13, 14, 15, 16, 17, and 18 illustrate schematic cross-sectional views at intermediate stages in the formation of a redistribution layer in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

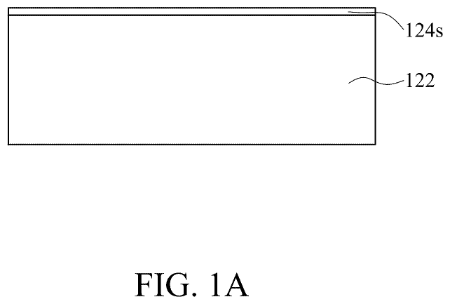

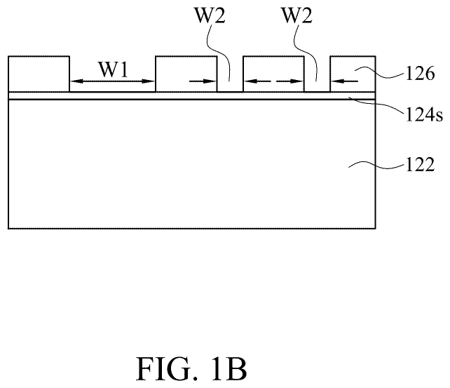

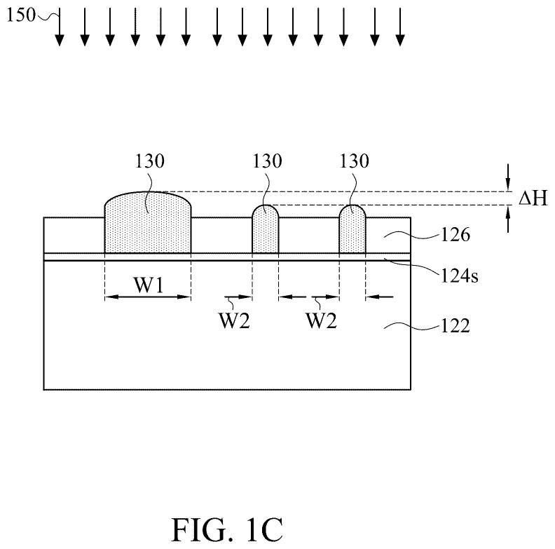

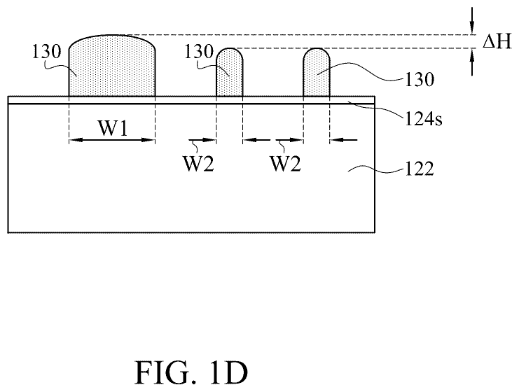

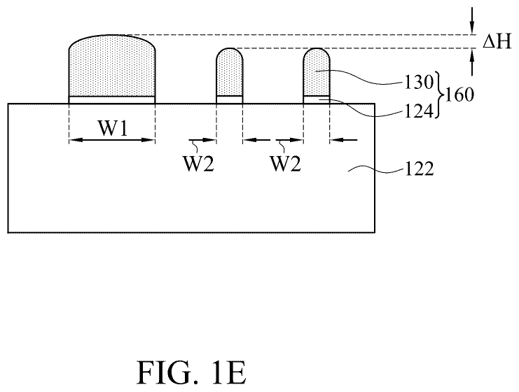

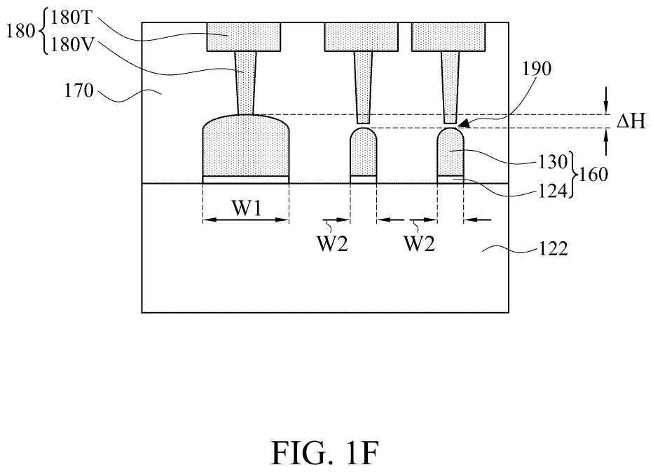

FIGS. 1A-1F are schematic cross-sectional views of various stages of forming a redistribution layer (RDL) in accordance with some embodiments. Referring to FIG. 1A, a seed material 124s is formed on a base layer 122. In some embodiments, the base layer 122 includes a polymer material such as polybenzoxazole (PBO), polyimide (PI), benzocyclobutene (BCB), Ajinomoto build-up film (ABF), or other suitable polymer materials. In some embodiments, the base layer 122 includes silicon-based materials, such as glass, silicon oxide, silicon carbide, silicon nitride, combinations of any of these materials, or the like. In some embodiments, the base layer 122 is a substrate which may be part of a semiconductor package, such as an integrated circuit (IC). In some embodiments, the base layer 122 includes a barrier layer overlying a semiconductor substrate, and the seed material 124s is formed on the barrier layer. The seed material 124s may be a thin film of a conductive material that aids in the formation of a thicker metallic layer during subsequent processing steps. For example, the seed material 124s includes a tantalum/copper bilayer, a copper layer, or other suitable metal layer. The seed material 124s may be deposited on the base layer 122 using suitable process such as sputtering, evaporation, physical vapor deposition (PVD), chemical vapor deposition (CVD), or plasma-enhanced CVD (PECVD) processes.

Referring to FIG. 1B, a photoresist layer 126 having openings 128 is formed on the seed material 124s. For example, the photoresist material is deposited on the seed material 124s by any suitable technique, such as spin coating, and then patterned according to a desired layout of redistribution pattern. In some embodiments, the photoresist material is patterned by lithography and etching process to form the photoresist layer 126 with the openings 128 accessibly revealing desired portions of the seed material 124s. For example, the photoresist material is exposed to a patterned light source, thereby inducing a physical change in those portions of the photoresist material exposed to the patterned light source, and then a developer applied to the photoresist material to selectively remove either the exposed portion of the photoresist material or the unexposed portion of the photoresist material, depending upon the characteristic of the photoresist material and the desired pattern. As to be discussed in further detail, metal lines will be formed in the openings 128. The openings 128 may have different widths, such as a larger width W1 and a smaller width W2 in the depicted embodiment, which corresponds to the to-be-formed metal lines of a larger width W1 and a smaller width W2, respectively.

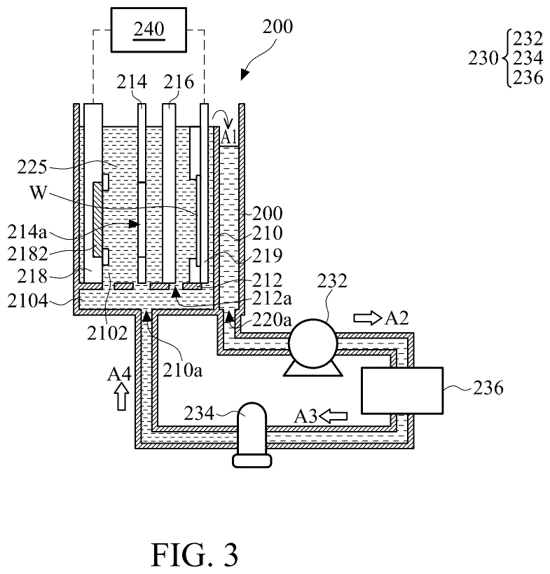

Referring to FIG. 1C, metal lines 130 are formed on the seed material 124s within the openings 128 of the photoresist layer 126. The portion of the metal lines 130 formed in those larger openings 128 inherit the larger width W1, and the portion of the metal lines 130 formed in those smaller openings 128 inherit the smaller width W2. By way of example, and not by limitation, the width and spacing of the metal lines 130 may each range between 1 μm and 50 μm. Other dimension of the metal lines 130 may be used. In some embodiments, the metal lines 130 include one or more conductive materials, such as copper, tungsten, other metals, metal alloy, or the like. The metal lines 130 may be formed by electroplating, electroless plating, or other suitable deposition process. In some embodiments in which an electroplating process (or electrochemical plating (ECP) process) 150 is used, the seed material 124s and the photoresist layer 126 are submerged or immersed in an electroplating solution (also referred to a plating bath), where the seed material 124s may function as the cathode in the electroplating process. A conductive anode disposed in the electroplating solution is attached to the positive side of the power supply, and the atoms from the conductive anode are dissolved into the electroplating solution, thereby plating the exposed conductive areas of the seed material 124s within the openings 128 of the photoresist layer 126. The details of the plating process will be described later in accompanying with FIG. 3.

As a result of loading effects, the wide metal lines 130 exhibit a larger surface area and generally experience a higher deposition rate compared to the narrow metal lines 130. Consequently, the conductive materials deposit more rapidly on the wide metal lines 130, causing them to grow in height at a faster rate. Upon completion of the ECP process 150, it is common for the height of the wide metal lines 130 to exceed that of the narrow metal lines 130. This disparity in height, denoted as ΔH, can often surpass 1 μm in certain embodiments.

Referring to FIG. 1D, the photoresist layer 126 is removed. For example, the photoresist layer 126 is stripped by etching, ashing, or other suitable removal processes. After the removal of the photoresist layer 126, a portion of the seed material 124s that is not covered by the plated metal lines 130 are exposed.

Referring to FIG. 1E, the portion of the seed material 124s that were covered by the photoresist layer 126 is then removed to form the seed layer 124. For example, by using the plated metal lines 130 as a mask, the portion of the seed material 124s is removed through etching until the base layer 122 is revealed. Up to here, forming a conductive pattern 160 including the metal lines 130 and the underlying seed layer 124 on the base layer 122 is substantially completed. The conductive pattern 160 may be referred to as a redistribution layer (RDL) in accordance with some embodiments.

Referring to FIG. 1F, a dielectric layer 170 is formed over the base layer 122 and over the RDL 160. The dielectric layer 170 may include multiple sub-layers each formed of an oxide, a nitride, or a combination thereof, such as USG or high density plasma (HDP) chemical vapor deposition oxide. Planarization processes, such as a chemical-mechanical-polishing (CMP) process, may be performed to planarize the deposited dielectric layer 170. Next, bonding pads 180 are formed in the dielectric layer 170. Each of the bonding pads 180 includes a bonding pad metal (BPM) 180T and a bonding pad via (BPV) 180V. The formation of a bonding pad 180 includes first etching the dielectric layer 170 to form a trench and a via opening and subsequently filling an electrically conductive material (e.g., copper, tungsten, other metals, metal alloy, or the like) in the trench and the via opening as the BPM 180T and the BPV 180V, respectively. The conductive materials in the bonding pads 180 and the RDL 160 may be the same or different, depending on device performance and/or cost requirements.

Still referring to FIG. 1F, the bonding pad vias 180V are depicted as extending from the upper surface of the dielectric layer 170 downward to the metal lines 130 in the RDL 160. However, a notable height difference ΔH between the wide and narrow metal lines 130 introduces a challenge. During the etching process, while the via openings above the wide metal lines 130 successfully expose them, the via openings above the narrow metal lines 130 may still be positioned over the narrow metal lines 130. Consequently, a gap 190 remains between the bonding pad vias 180V above the narrow metal lines 130. This discontinuity between the narrow metal lines 130 and the bonding pad vias 180V poses a defect, leading to circuit malfunctions. Even in cases where over etching is applied to expose the narrow metal lines 130 in the via opening, the exposure may prove insufficient, resulting in high contact resistance between the narrow metal lines 130 and the bonding pad vias 180V, thereby deteriorating circuit performance. Moreover, excessive etching can lead to lateral expansion of trenches and via openings, raising the risk of shorting to adjacent metal features as IC manufacturing processes progress into the sub-micron era.

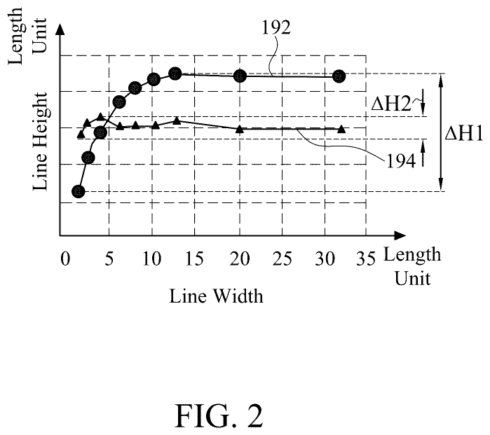

In accordance with some embodiments, FIG. 2 showcases a comparison between metal line heights and metal line widths under a conventional electroplating process and a modified electroplating process. The diagram illustrates two lines: line 192 represents the conventional electroplating process, where the metal line height generally increases as the metal line width expands due to loading effects. Consequently, the maximum height difference ΔH1 can exceed 1 μm. On the other hand, line 194 represents the modified electroplating process, which will be discussed in detail shortly. Although the metal line height still generally increases with a larger metal line width, the modified process imposes stringent control over the maximum height difference ΔH2. In fact, ΔH2 is approximately one fifth of ΔH1. In some embodiments, ΔH2 is less than about 0.5 μm, such as less than about 0.4 μm, less than about 0.3 μm, or less than about 0.2 μm.

FIG. 3 is a schematic cross-sectional view of electroplating apparatus for performing an electroplating process in accordance with some embodiments. Referring to FIG. 3, an electroplating apparatus 200 includes a plating tank 210 configured to containing a plating bath (e.g., a plating solution 225) and an overflow tank 220 connected to the plating tank 210 for receiving the plating solution 225 that has overflowed an edge of the plating tank 210. In some embodiments, a separation plate 212 is disposed in the plating tank 210 to partition the interior of the plating tank 210 into a processing chamber 2102 and a distribution chamber 2104, where the distribution chamber 2104 is located in proximity to an inlet 210a of the plating tank 210. In some embodiments, the separation plate 212 is disposed horizontally to divide the plating tank 210 into an upper portion (e.g., processing chamber 2102) and a lower portion (e.g., the distribution chamber 2104). Although other orientation of the separation plate 212 may be used. For example, a plurality of passage holes 212a is provided in the separation plate 212 for passage of the plating solution 225. In some embodiments, the plating solution 225 flows from the inlet 210a to the distribution chamber 2104 and passes through the passage holes 212a of the separation plate 212 to fill the processing chamber 2102. For example, the passage holes 212a are distributed in the separation plate 212 in a manner to allow the plating solution 225 passing through the passage holes 212a to form a uniform flow toward the processing chamber 2102.

In some embodiments, an anode 2182 carried by an anode holder 218 and a work-piece holder 219 carrying a work piece W may be disposed in the plating tank 210 and immersed in the plating solution 225 contained in the processing chamber 2102. For example, the anode holder 218 and the work-piece holder 219 are disposed in a vertical manner in the processing chamber 2102. Alternatively, the anode holder 218 and the work-piece holder 219 are horizontally disposed in the plating tank 210. In some embodiments, the electroplating apparatus 200 includes a regulation plate 214 and a paddle 216 disposed inside the processing chamber 2102 of the plating tank 210. For example, the regulation plate 214 and the paddle 216 are arranged between the anode holder 218 and the work-piece holder 219. In some embodiments, the anode holder 218 and the work-piece holder 219 are disposed along two opposing sidewalls of the plating tank 210, and the regulation plate 214 and the paddle 216 are disposed parallel to the work piece W held by the work-piece holder 219. The regulation plate 214 may be located in proximity to the anode 2182 held by the anode holder 218, and the paddle 216 may be located between the regulation plate 214 and the work-piece holder 219.

In some embodiments, at least one through hole 214a is provided in the regulation plate 214 and configured to adjust the electric field distribution of the work piece W in the plating tank 210. It is noted that although one through hole is illustrated in FIG. 3, a plurality of the through holes may be distributed in the regulation plate 214 depending on process requirements. In some embodiments, the paddle 216 is configured to be moving in the plating tank 210 to stir the plating solution 225 into a uniform mass. It is also noted that although a single paddle is illustrated in FIG. 3, a plurality of the paddles may be disposed in the plating tank 210 to thoroughly mix the plating solution 225. In some embodiments, the electroplating apparatus 200 includes a power supply 240 electrically coupled to the anode 2182 and the work-piece holder 219 carrying the work piece W to be processed. For example, the anode 2182 includes a source of a metal (e.g., copper) that is to be plated onto the work piece W.

Still referring to FIG. 3, the electroplating apparatus 200 may include a supply unit 230 in communication with the plating tank 210 and the overflow tank 220. For example, the supply unit 230 includes a pump 232 in communication with the outlet 220a of the overflow tank 220 and configured to convey the plating solution 225 discharging from the overflow tank 220 toward the inlet 210a of the plating tank 210 through pipeline. In some embodiments, the supply unit 230 includes a carbon filter 234 disposed downstream of the pump 232 and configured to remove contaminant in the return flow of the plating solution 225 before entering the inlet 210a of the plating tank 210. For example, the pump 232 continuously pumps the plating solution 225 through the carbon filter 234 to provide the circulation. The pump 232 may be referred to as a circulating pump. In some embodiments, the plating solution 225 overflows from the edge of the plating tank 210 to the overflow tank 220 as indicated by arrows A1, and then the plating solution 225 discharged from the outlet 220a of the overflow tank 220 is pumped and filtered before returned to the plating tank 210 as indicated by arrows A2-A4, thereby completing recirculation.

The supply unit 230 may include a temperature controller 236 for controlling the temperature of the plating solution 225. For example, the temperature controller 236 includes thermostatic controller, heater, cooler, temperature sensor, combination of these, etc. It is noted that during the electroplating, quality of the plated conductive layer may be affected by the temperature of the electrolyte. In some embodiments, the temperature of the return flow of the plating solution 225 is regulated via the temperature controller 236 to meet the plating conditions. In some embodiments, the temperature controller 236 is disposed downstream of the pump 232. For example, the temperature controller 236 is arranged between the pump 232 and the carbon filter 234 to regulate the temperature of the plating solution 225 before flowing through the carbon filter 234. In some embodiments, the temperature controller 236 is disposed downstream of the carbon filter 234 to control the temperature of the plating solution 225 before filling the plating tank 210. Alternatively, the temperature controller 236 is disposed between the outlet 220a of the overflow tank 220 and the pump 232. It is noted that although a single pump, a single filter and a single temperature controller are illustrated in FIG. 3, the numbers of the pump, filter, and temperature controller construe no limitation in the disclosure. The electroplating apparatus 200 may include additional elements which are not shown for the purpose of simplicity and clarity.

Still referring to FIG. 3 and also with reference to FIGS. 1B-1C, for example, during an electrochemical plating cycle, the work piece W (such as the structure shown in FIG. 1B) is mounted onto the work-piece holder 219, and then placed in the processing chamber 2102 of the plating tank 210 to be immersed in the plating solution 225. The power supply 240 (e.g., a DC power supply) may be electrically coupled to a control system (not shown) and may provide a negative output to the work piece W and a positive output to the anode 2182 to perform a plating process (e.g., the electroplating process 150 shown in FIG. 1C). For example, an electrochemical reaction (e.g., Cu²⁺+2e⁻→Cu) on the work piece W may result in deposition of the conductive layer (e.g., copper layer) thereon, and the oxidation reaction (e.g., Cu→Cu²⁺+2e⁻) may take place at the anode 2182 to replenish the ion concentration of the plating solution 225. It is noted that embodiments of the disclosure may be applied to other suitable electrochemical reaction and the deposition of other conductive materials.

The plating solution 225 may be initially prepared and provided in the plating tank 210 for the electrochemical plating. For example, the plating solution 225 includes a metal salt containing ions of the metal to be electroplated on the work piece W. In some embodiments in which the copper layer is to be plated, the plating solution 225 includes a mixture of copper salt, acid, and water. For example, copper salts used in the plating solution 225 include copper sulfate, copper fluoride, copper cyanide, copper nitrate, copper oxide, copper fluoroborate, copper pyrophosphate, or the like. The acids used in the plating solution 225 may include sulfuric acid, fluoroboric acid, nitric acid, and phosphoric acid, or the like. However, embodiments of the disclosure are not limited thereto. The concentration of the copper salt and the concentration of acid used in the plating solution 225 may vary depending on the particular copper salt and acid used.

In some embodiments, the plating solution 225 is a liquid solution consisting of copper sulfate (CuSO₄) for the main electrolyte, electrically conductive agent (e.g., sulfuric acid (H₂SO₄)), anode dissolution agent (e.g., hydrochloric acid (HCl)), and water (H₂O) used as a solvent. The sulfuric acid disassociates the copper ions from the copper sulfate, allowing the copper sulfate to migrate to the exposed seed layer and form copper plate, while the chloride ions prevent copper oxide generated by the reaction between the copper ions in the plating solution and oxygen (O₂) in the environment. In a conventional electroplating process, a ratio of the concentration of copper ions and sulfuric acid is about 1 or larger than 1, and a ratio of the concentration of copper ions and hydrochloric acid is about 1 or larger than 1, such as Cu²⁺:H₂SO₄:Cl⁻=1:1:1 in one example. In such a conventional electroplating process, the relatively high concentration of copper ions in the plating solution 225 is mainly to promote copper deposition rate and increase production throughput. However, due to the loading effect, copper ions have a tendency to more easily deposit on the seed layer with a larger surface, and a high concentration of copper ions in the plating solution 225 escalates the growth rate at the locations of the wide metal lines and further aggravates the height difference. Therefore, to reduce the height difference between the wide and narrow metal lines, one way is to reduce the concentration of copper ions. In some embodiments, a ratio of the concentration of copper ions and sulfuric acid is in a range from about 1:2 to about 1:4, such as in a range from about 1:2.5 to about 1:3. Further, increasing the concentration of hydrochloric acid can balance copper deposition rate in different regions by preventing copper ions from fast deposition at the locations of the wide metal lines. In some embodiments, a ratio of the concentration of copper ions and hydrochloric acid is in a range from about 1:2 to about 1:3.8, such as in a range from about 1:2.2 to about 1:3. Still further, the concentration of sulfuric acid may be intentionally kept a little bit higher than the concentration of hydrochloric acid to promote disassociating the copper ions from the copper sulfate. In other words, other than the conventional electroplating process in which a ratio of Cu²⁺: H₂SO₄: Cl⁻ is about 1:1:1, a modified plating solution 225 may reduce the concentration of Cu²⁺ about 30% to about 45%, increase the concentration of H₂SO₄ about 70% to 90%, and increase the concentration of Cl⁻ about 50% to 70%. These modified amounts of the concentrations are not arbitrary, as if the modified amounts are less than the lower bounds of the illustrated ranges, the copper deposition rate may be too low and dramatically slow down the manufacturing throughput; and if the modified amounts are larger than the upper bounds of the illustrated ranges, the height difference between the wide and narrow metal lines may be too large and easily deteriorate the circuit performance.

In some embodiments, the plating solution 225 is a liquid solution that further includes a first additive, a second additive, and a third additive. The first additive may be referred to as an accelerator, which is responsible for enhanced plating rate. The accelerator promotes a smooth and bright deposit. Therefore, the accelerator may also be referred to as a brightener. In some embodiments, the accelerator may include Bis (3-sulfopropyl) disulfide, 3-mercapto-propylsulfonic acid, 3-mercapto-propylsulfonic acid-(3-sulfopropyl) ester, or the like. The second additive may be referred to as a suppressor, which combine with chloride ions to inhibit plating on areas where a reduced plating rate is needed, and can also act as a wetting agent. In some embodiments, the suppressor inhibits the grow of copper oriented at a (111) copper lattice plane but promotes the growth of copper oriented at a (220) copper lattice plane. Owing to the suppressor, the growth orientation of the copper grains on the seed layer can be fine-tuned, where the copper ions are disposed on the exposed seed layer with a (220) crystallization. The third additive may be referred to as a leveler. The leveler polarizes the areas with high current densities and evens out current distribution, and helps control the surface morphology. The leveler typically remains at the top surface and slows over-plating to give a smooth deposit. For example, the leveler may include alkylated polyalkyleneimine, 2-mercatothiazoline, or the like. During the RDL formation, the suppressor wets the photoresist and the leveler enters the openings defined by the photoresist during the plating process, to help create a pillar with a flat top. Both the leveler and the suppressor are polarizing agents that help control the plating uniformity across different die and wafer, while the accelerator acts as a copper grain refiner, making a smooth and bright deposit.

In a conventional electroplating process, the concentrations of the accelerator, suppressor, and leveler are close to each other, such that a ratio of the concentrations among the accelerator, suppressor, and leveler is about 1:1:1 in one example. Although the leveler generally helps to slow over-plating to give a smooth deposit, counter-intuitively lowering the concentration of leveler may promote the copper deposition rate at the locations of narrow metal lines by the intentional introduction of “over-plating” at those locations. The otherwise unwanted “over-plating” at the locations of narrow metal lines actually helps mitigating the height difference between the wide and narrow metal lines at a resultant RDL structure. In some embodiments, the concentrations of the accelerator and the suppressor are remained the same (e.g., about 1:1), while the concentration of the leveler is reduced about 30% to about 50%. For example, a ratio of the concentrations among the accelerator, suppressor, and leveler may in a range from about 1:1:0.5 to about 1:1:0.7. This range is not arbitrary, as if the concentration of the leveler in the ratio is less than about 0.5, amount of the leveler may be insufficient in the plating solution and deteriorate plating quality; and if the concentration of the leveler in the ratio is larger than about 0.7, the amount of leveler may not effectively promote the “over-plating” at the locations of narrow metal lines to compensate the height difference.

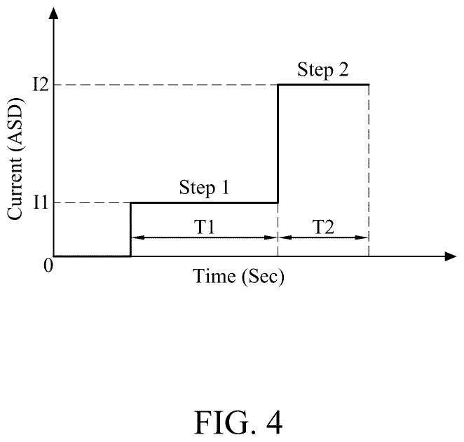

Reference now is made to FIG. 4. FIG. 4 is a diagram illustrating a multi-step process of applying different plating currents during the electroplating process. In a conventional electroplating process, a constant and relatively large current (e.g., above 0.6 amps per square decimeter (ASD)) may be applied by the power supply 240 of the electroplating apparatus 200. A relatively large current promotes a larger copper grain size, reduces surface roughness of a plated conductive layer, suppresses impurities, and increases manufacturing throughput. As a comparison, a relatively small current may lead to a smaller copper grain size, a larger surface roughness of a plated conductive layer, a higher concentration of impurities, and a lower manufacturing throughput. However, under a relatively large current, copper ions have a strong tendency to deposit at the seed layer of a larger surface area, while under a relatively small current, the deposition rates at different locations do not deviate much. As the discrepancy of the deposition rates at an early phase of the growth of a plated conductive layer has more weight than at a later phase of the growth of a plated conductive layer, in the present embodiment, a two-step process of applying a small plating current I1 (e.g., less than about 0.6 ASD) as a first step and applying a high plating current 12 (e.g., larger than about 0.6 ASD) as a second step is implemented. In some embodiments, the current I1 may range from about 0.1 ASD to about 0.5 ASD, and the current 12 may range from about 0.7 ASD to about 2 ASD. In furtherance of the embodiments, a ratio of 12 and I1 may range from about 2:1 to about 5:1. This range is not trivial, as if 12: I1 is larger than about 5:1, the benefits of applying a smaller current to reduce height difference is not obvious; and if 12: I1 is smaller than about 2:1, the copper grain size and roughness may deteriorate circuit performance and the manufacturing throughput may become too low. In furtherance of some embodiments, applying the small plating current I1 may last for a duration of T1, and applying the big plating current 12 may last for a duration of T2, in which T1 may be longer than T2 to compensate a relatively low deposition rate at a small plating current I1.

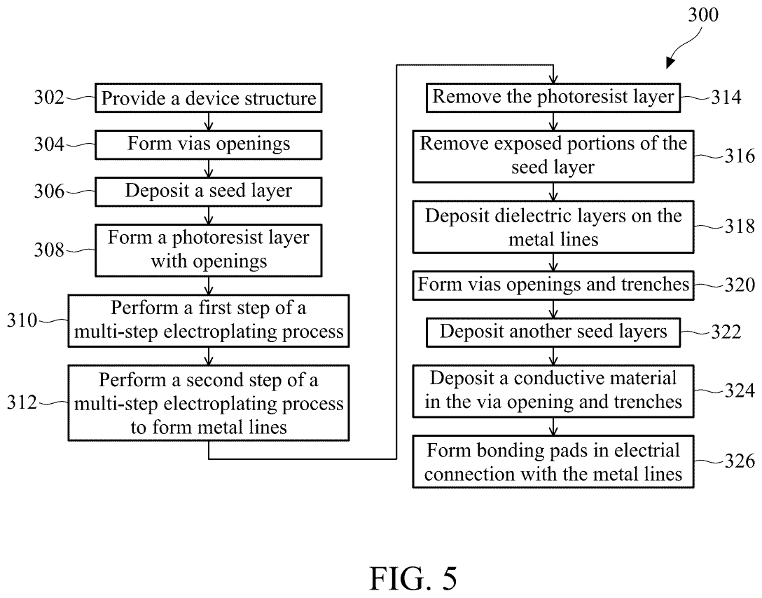

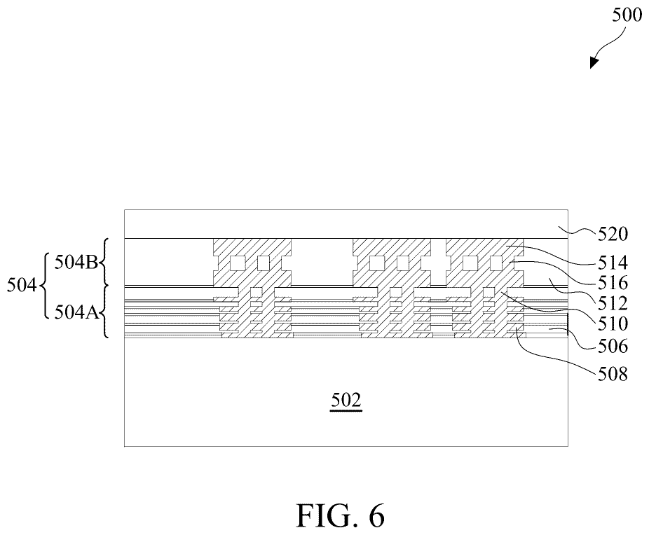

FIG. 5 illustrates a flow chart of a method 300 for forming an RDL structure in accordance with some embodiments. The method 300 is merely an example, and is not intended to limit the present disclosure beyond what is explicitly recited in the claims. Additional operations can be provided before, during, and after the method 300, and some operations described can be replaced, eliminated, or moved around for additional embodiments of the method. The method 300 is described below in conjunction with FIGS. 6-18, which illustrate various cross-sectional views of a device structure (or device) 500 during fabrication steps according to the method 300.

At operation 302, the method 300 (FIG. 5) provides, or is provided with, a device structure 500 having a substrate 502, metallization layers 504, and a dielectric layer 520, such as shown in FIG. 6. In various embodiments, the device structure 500 is a wafer, such as a silicon wafer.

In some embodiments, the substrate 502 may comprise crystalline silicon, crystalline germanium, silicon germanium, a III-V compound semiconductor such as GaAsP, AlInAs, AlGaAs, GaInAs, GaInP, GalnAsP, or the like. The substrate 501 may also be a bulk silicon substrate or a Silicon-On-Insulator (SOI) substrate. Shallow Trench Isolation (STI) regions (not shown) may be formed in the substrate 502 to isolate active regions (if presented) in the substrate 502. Although not shown, through-vias may be formed to extend into the substrate 502, wherein the through-vias are used to electrically inter-couple the features on opposite sides of the device structure 500.

In the illustrated embodiment in FIG. 6, the metallization layers 504 include lower metallization layers 504A and upper metallization layers 504B. The lower metallization layers 504A includes a plurality of dielectric layers 506 formed of, e.g., extreme low-K (ELK) material, and electrically conductive features (e.g., metal lines 508, vias 510) formed in the dielectric layers 506. The upper metallization layers 504B includes a plurality of dielectric layers 512 formed of, e.g., un-doped silicate glass (USG), and electrically conductive features (e.g., metal lines 514, vias 516) formed in the dielectric layers 512. In some embodiments, the dimensions (e.g., thicknesses and/or widths of the metal lines/vias, or spacing between adjacent metal lines or vias) of the electrically conducive features (e.g., lines, vias) in the upper metallization layers 504B are larger than the corresponding dimensions of the electrically conducive features in the lower metallization layers 504A.

The dielectric layer 520 is formed over the upper metallization layers 504B. In some embodiments, the dielectric layer 520 is an inter-metal dielectric (IMD) layer or an inter-layer dielectric (ILD) layer. The dielectric layer 520 may comprise a dielectric material such as an oxide, a nitride, a carbon-containing dielectric material, or the like. For example, the dielectric layer 520 may be formed of phospho silicate glass (PSG), boro silicate glass (BSG), boron-doped phospho silicate glass (BPSG), fluorine-doped silicate glass (FSG), a silicon oxide layer (formed using tetra ethyl ortho silicate (TEOS)), or the like. The dielectric layer 520 may be formed using spin-on coating, atomic layer deposition (ALD), flowable chemical vapor deposition (FCVD), chemical vapor deposition (CVD), plasma-enhanced chemical vapor deposition (PECVD), low-pressure chemical vapor deposition (LPCVD), or the like. In some embodiments, the dielectric layer 520 may be a low-k dielectric layer having a low dielectric constant value lower than about 3.5 or lower than about 3.0.

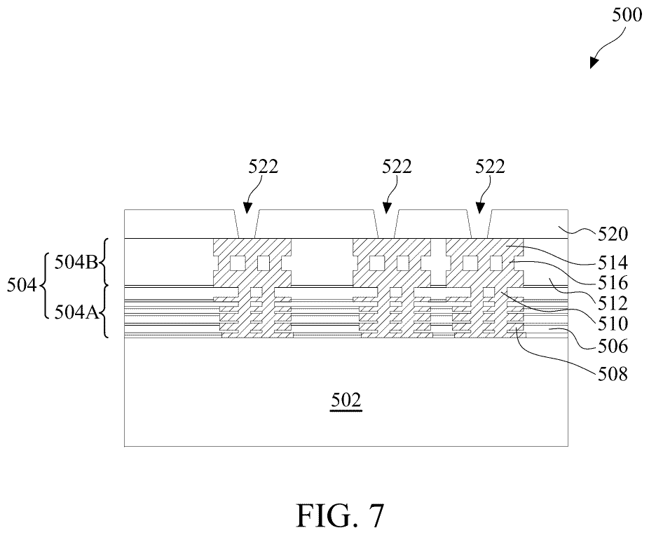

At operation 304, the method 300 (FIG. 5) forms via openings 522 through the dielectric layer 520, such as shown in FIG. 7. In some embodiments, the via openings 522 may be formed using, for example, photolithography techniques. In an example of the formation process of the via openings 522, a hard mask (not shown) is first formed and patterned. The patterned hard mask includes openings through which the dielectric layer 520 is etched. The dielectric layer 520 is then etched to form the opening 522. The etching process may be an anisotropic etching process, in which the via openings 522 extend down until the metal lines 514 are exposed.

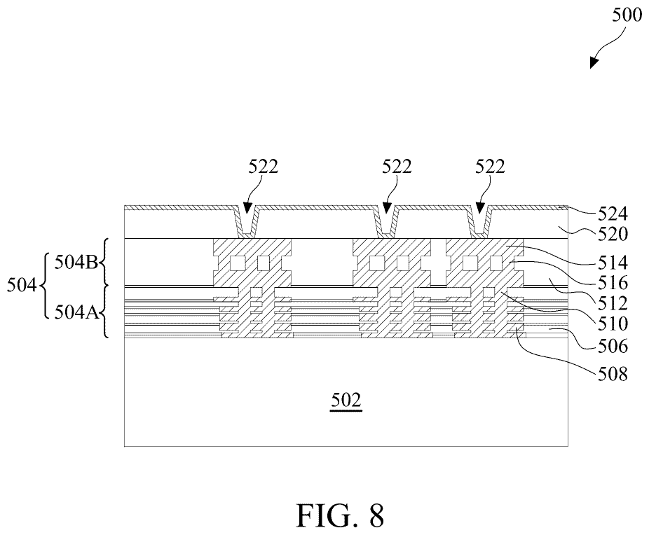

At operation 306, the method 300 (FIG. 5) conformally deposits a seed layer 524 over the device structure 500, such as shown in FIG. 8. The seed layer 524 may be a thin film of a conductive material that aids in the formation of a thicker metallic layer during subsequent processing steps. For example, the seed layer 524 includes a tantalum/copper bilayer, a copper layer, or other suitable metal layer. The seed layer 524 may be deposited by using ALD, CVD, ELD, PVD, or other suitable deposition techniques. In some embodiments, a barrier layer (not shown) is conformally deposited over the device structure 500 prior to the deposition of the seed layer 524. The barrier layer may be formed of a conductive material such as Ta, TaN, TaC, Ti, TIN, TiC, and other suitable material that can block metal element diffusion into the dielectric layer 520, and may be deposited using ALD, CVD, ELD, or PVD, or other suitable deposition techniques.

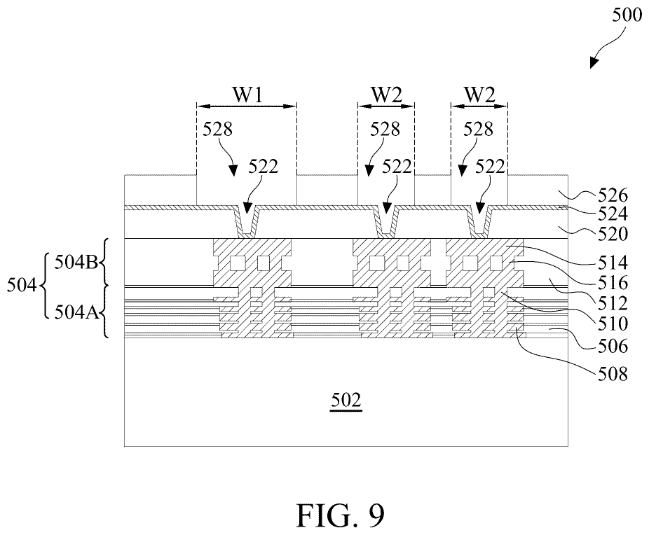

At operation 308, the method 300 (FIG. 5) forms a photoresist layer 526 on the seed layer 524, such as shown in FIG. 9. The photoresist layer 526 has trenches 528 overlying the via openings 522. In some embodiments, a photoresist material may be deposited on the seed layer 524 by any suitable technique, such as spin coating, and then patterned according to a desired layout of a redistribution pattern. In some embodiments, the photoresist material is patterned by lithography and etching process to form the photoresist layer 526 with the trenches 528 accessibly revealing desired portions of the seed layer 524 and the via openings 522. For example, the photoresist material is exposed to a patterned light source, thereby inducing a physical change in those portions of the photoresist material exposed to the patterned light source, and then a developer applied to the photoresist material to selectively remove either the exposed portion of the photoresist material or the unexposed portion of the photoresist material, depending upon the characteristic of the photoresist material and the desired pattern. As to be discussed in further detail, vias will be formed in the via openings 522, and metal lines will be formed in the trenches 528. The trenches 528 may have different widths, such as a larger width W1 and a smaller width W2 in the depicted embodiment, which corresponds to to-be-formed metal lines of a larger width W1 and a smaller width W2, respectively.

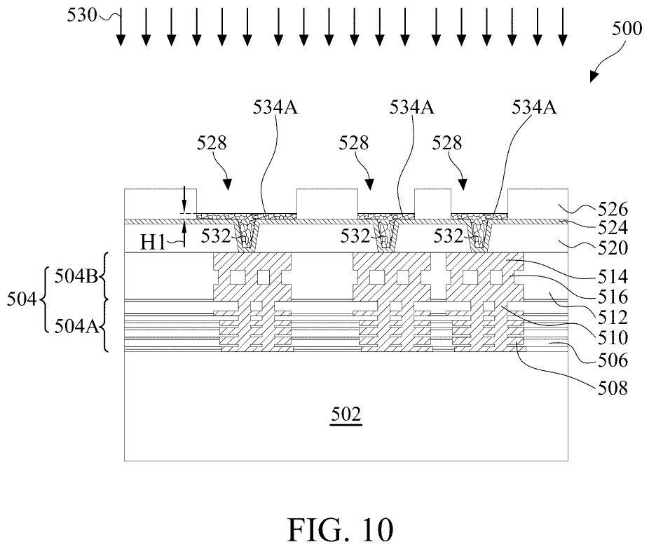

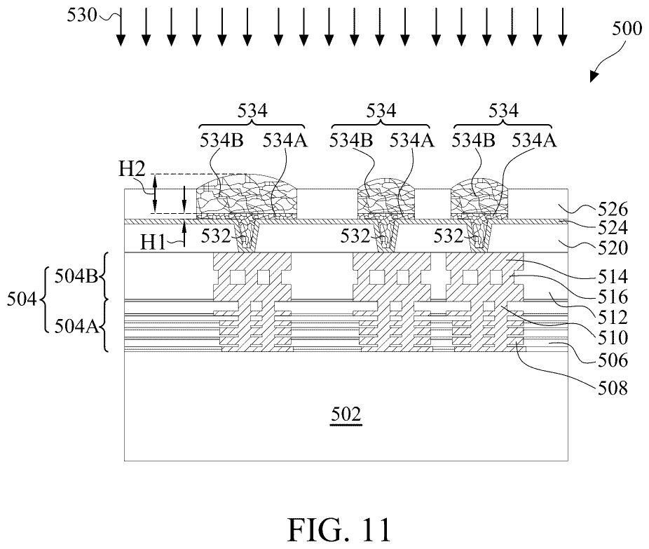

At operation 310, the method 300 (FIG. 5) performs a first step of a multi-step electroplating process 530. The multi-step electroplating process 530 may be similar to the multi-step electroplating process as described above with respect to FIG. 4, in which a relatively small plating current I1 is applied to a plating solution. The plating solution may be similar to the plating solution 225 as described above with respect to FIG. 3. The resultant structure after performing the first step of the multi-step electroplating process 530 is shown in FIG. 10. In the illustrated embodiment, copper is first plated in the via openings 522 and fills up the via openings 522. As the electroplating process 530 (still with the small plating current 11) continues, plated copper extends upwardly in a continuous form and fills a bottom portion of the trenches 528. The portion of the copper formed in the via openings 522 becomes the vias 532, and the other portion of the copper formed in the bottom portion of the trenches 528 becomes a bottom portion 534A of the metal lines 534 (FIG. 11). A thickness of the bottom portion 534A of the metal lines 534 is denoted as H1.

At operation 312, the method 300 (FIG. 5) performs a second step of the multi-step electroplating process 530, in which a relatively large plating current 12 is applied to the plating solution. The plating solution may be the same plating solution as used in operation 310. The resultant structure after performing the second step of the multi-step electroplating process 530 is shown in FIG. 11. In the illustrated embodiment, plated copper extends upwardly from the top surface of the bottom portion 534A and fills a top portion of the trench openings 528, and even exceeds a top surface of the photoresist layer 526. The portion of the copper formed in the top portion of the trenches 528 becomes a top portion 534B of the metal lines 534. A thickness of the top portion 534B of the metal line 534 is denoted as H2. The total thickness of the metal lines 534 is thus H1+H2. In some embodiments, the first step of the multi-step electroplating process 530 is switched to the second step of the multi-step electroplating process 530 when a thickness of the bottom portion 534A (H1) reaches about 10% to about 20% of the thickness of the metal lines 534 (H1+H2). In other words, a ratio of H1: H1+H2 ranges from about 10% to about 20%. This range is not trivial, as if the ratio is less than 10%, the benefits of applying a smaller current to reduce height difference is not obvious; and if the ratio is larger than about 20%, the smaller copper grain size and larger roughness in an otherwise thicker bottom portion 534A may deteriorate circuit performance and the manufacturing throughput may become too low.

Due to the smaller plating current applied at the first step of the electroplating process 530, the vias 532 and the bottom portion 534A of the metal lines 534 have a smaller copper grain size, a larger surface roughness, and a higher concentration of impurities. Due to the larger plating current applied at the second step of the electroplating process 530, the top portion 534B of the metal lines 534 has a larger copper grain size, a smaller surface roughness, and a lower concentration of impurities. In some embodiments, an average grain size of the copper grains in the vias 532 and the bottom portion 534A of the metal lines 534 ranges from about 0.2 μm to about 0.5 μm, and an average grain size of the copper grains in the top portion 534B of the metal lines 534 ranges from about 1 μm to about 1.5 μm. In some embodiments, a surface roughness at the top surface of the bottom portion 534A of the metal lines 534 ranges from about 100 nm to about 150 nm, and a surface roughness at the top surface of the top portion 534B of the metal lines 534 ranges from about 30 nm to about 80 nm. It is appreciated that the average grain size and the surface roughness of the bottom and top portions of the metal lines 534 depend on the details of the plating process and may be less than or greater than the aforementioned ranges.

The metal lines 534 formed by the electroplating process may include impurities (e.g., carbon (C), nitrogen (N), oxygen (O), sulfur(S), and chlorine (Cl)) due to the nature of the plating process. For example, the concentration of impurities in the metal lines 534 may be analyzed by secondary ion mass spectrometry (SIMS) for copper, C, N, O, S, and Cl. It is noted that the copper impurity concentration is measured in terms of the concentration in parts per million (ppm). In some embodiments, the concentration of impurities in the vias 532 and the bottom portion 534A of the metal lines 534 ranges from about 10 ppm to about 100 ppm, and the concentration of impurities in the top portion 534B of the metal lines 534 ranges from about 0.1 ppm to about 1 ppm. It is appreciated that the concentration of impurities of the bottom and top portions of the metal lines 534 depend on the details of the plating process and may be less than or greater than the aforementioned ranges.

Notably, FIGS. 10 and 11 illustrate the electroplating process 530 as a two-step process, other embodiments contemplate that the electroplating process 530 as a single-step process, a three-step process, or multi-step process with steps larger than three. In some embodiments, the electroplating process 530 may be a single-step process with a constant relatively small current, such as 0.5 ASD in one example, or 0.3 ASD in another example. The copper grain size, surface roughness, and concentration of impurities may thus be consistent from bottom to top of the metal lines 534. The metal line height difference may still be well controlled due to the benefits of applying a relatively small current and the recipe of the plating solution as discussed above that balances the deposition rates at locations of different metal line widths. In some embodiments, the electroplating process 530 may be a three-step process starting with a small current, transitioning into a medium current, and finishes at a strong current. Thus, the bottom, middle, and top portions of the metal lines 534 may have three regions of different copper grain sizes, surface roughness, and concentrations of impurities.

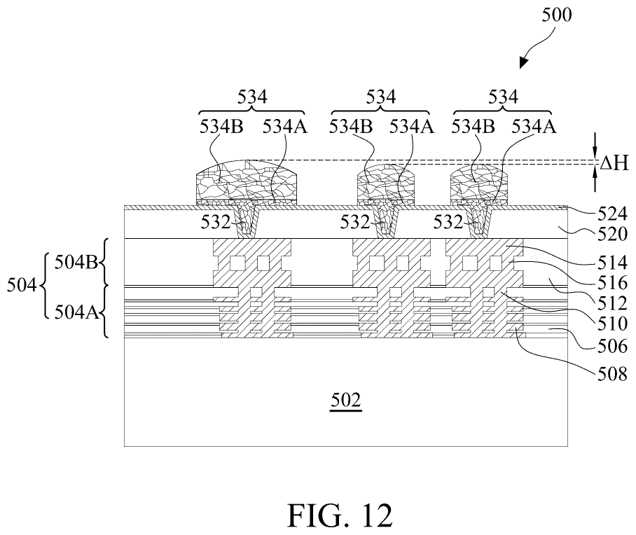

At operation 314, the method 300 (FIG. 5) removes the photoresist layer 526, such as shown in FIG. 12. For example, the photoresist layer 526 is stripped by etching, ashing, or other suitable removal processes. After the removal of the photoresist layer 526, a portion of the seed layer 524 that is not covered by the metal lines 534 are exposed. Also as shown in FIG. 12, the wide metal lines 534 may still be higher than the narrow metal lines 534, but the height difference ΔH is stringently controlled, which is represented by the line 194 (e.g., ΔH2) in FIG. 2 as being much smaller than by the conventional electroplating process as represented by the line 192 (e.g., ΔH1) in FIG. 2 as a comparison. In some embodiments, the height difference ΔH is less than about 0.4 μm in some embodiments, or less than about 0.3 μm in some other embodiments, or less than about 0.2 μm in yet some other embodiments. Prior to the removal of the photoresist layer 526, a CMP process may optionally be performed to level the top surfaces of the wide and narrow metal lines 534.

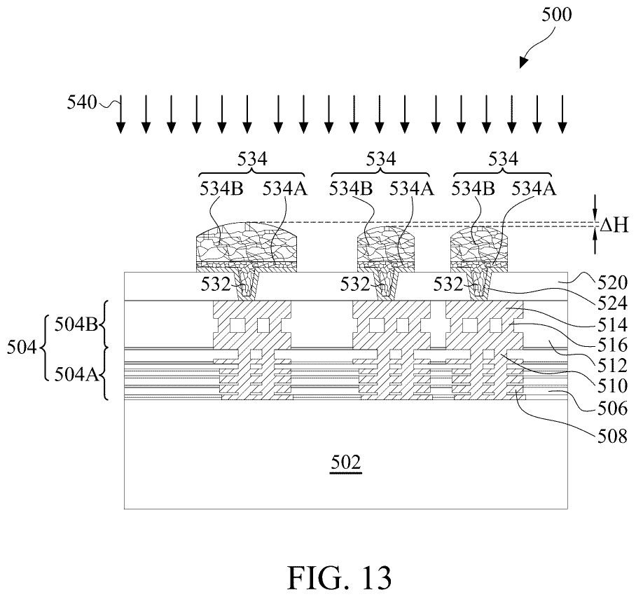

At operation 316, the method 300 (FIG. 5) removes the portion of the seed layer 524 that have been exposed after the removal of the photoresist layer 526, such as shown in FIG. 13. For example, by using the metal lines 534 as a mask, the portion of the seed layer 524 is removed through an etching process 540 until the dielectric layer 520 (or an etch stop layer deposited on the dielectric layer 520 if presented) is revealed. In one example, the etching process 540 includes applying a dry (or plasma) etch to remove the exposed portions of the seed layer 524. In another example, the etching process 540 includes applying a wet etch with a hydrofluoric acid (HF) solution to remove the exposed portions of the seed layer 524. In some embodiments, the dimensions (e.g., thicknesses and/or widths of the metal lines/vias, or spacing between adjacent metal lines or vias) of the metal lines 534 and the vias 532 are larger than the corresponding dimensions of the electrically conducive features in the metallization layers 504.

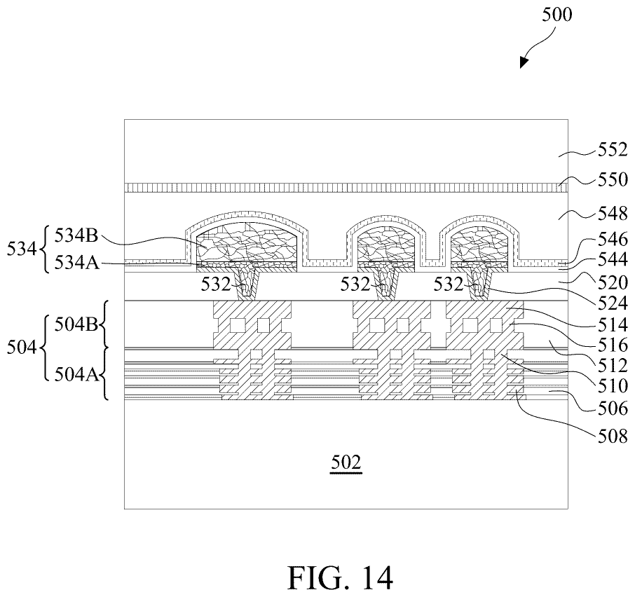

At operation 318, the method 300 (FIG. 5) sequentially deposits a plurality of dielectric layers on the device structure 500, such as shown in FIG. 14. In some embodiment, a first etch stop layer 544 is conformally deposited on sidewalls and top surfaces of the metal lines 534 and the top surface of the dielectric layer 520. The first etch stop layer 544 may comprise silicon nitride, silicon oxynitride, and/or other suitable materials. In some embodiments, a protective dielectric layer 546 is conformally deposited on the first etch stop layer 544. The protective dielectric layer 546 may comprise silicon oxide, undoped silicate glass (USG), and/or other suitable materials. In some embodiments, an IMD layer 548 is deposited on the protective dielectric layer 546. The IMD layer 548 may comprise SiO₂, borophosphosilicate glass (BPSG), high density plasma (HDP) oxide, spin on glass (SOG), undoped silica glass (USG), fluorinated silica glass (FSG), or other insulating materials. After the deposition of the IMD layer 548, a CMP process may be performed to planarize the top surface of the IMD layer 548. In some embodiments, a second etch stop layer 550 is deposited on the IMD layer 548. The second etch stop layer 550 may comprise silicon nitride, silicon oxynitride, and/or other suitable materials. In some embodiments, a dielectric layer 552 is formed on the second etch stop layer 550. The dielectric layer 552 may comprise undoped silica glass (USG), silicon oxide from silane (SiH₄) by plasma enhanced CVD, silicon oxide from tetraethoxysilane (TEOS) by plasma enhanced CVD, or high density plasma (HDP) CVD, spin-on glass, or combinations thereof.

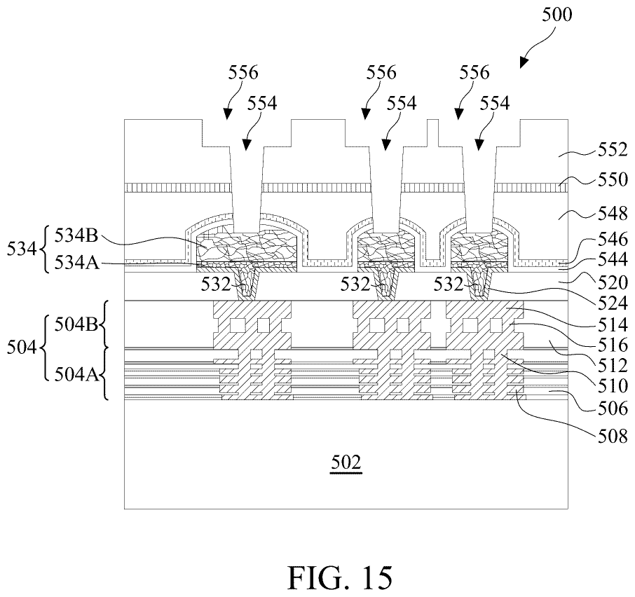

At operation 320, the method 300 (FIG. 5) forms via openings 554 and trenches 556 in the dielectric layers 544-552 through one or more etching processes, such as shown in FIG. 15. The via openings 554 and the trenches 556 may be formed using, for example, photolithography techniques. In accordance with some embodiments of the present disclosure, the etching of the dielectric layer 552 is performed using a process gas comprising fluorine and carbon, wherein fluorine is used for etching, with carbon having the effect of protecting the sidewalls of the resulting opening. For example, the process gases for the etching include a fluorine and carbon-containing gas(es) such as C₄F₈, CH₂F₂, and/or CF₄, and a carrier gas such as N₂. In an example of the etching process, the flow rate of C₄F₈ is in the range between about 0 sccm and about 50 sccm, the flow rate of CF₄ is in the range between about 0 sccm and about 300 sccm (with at least one of C₄F₈ having a non-zero flow rate), and the flow rate of N₂ is in the range between about 0 sccm and about 200 sccm. In accordance with alternative embodiments, the process gases for the etching include CH₂F₂ and a carrier gas such as N₂. In an example of the etching process, the flow rate of CH₂F₂ is in the range between about 10 sccm and about 200 sccm, and the flow rate of N₂ is in the range between about 50 sccm and about 100 sccm.

The etching for forming the via openings 554 may be performed using a time-mode. As a result of the etching, the via openings 554 is formed to extend to an intermediate level between the top surface and the bottom surface of the dielectric layer 552. Next, a further etching of the dielectric layer 552 is performed using a hard mask defining openings as locations for the trenches 556. In the etching process, which is an anisotropic etching process, the via openings 554 extend down until the etch stop layer 544 is exposed. At the same time the via openings 554 is extended downwardly, the trenches 556 are formed to extend into the dielectric layer 552. A subsequent etching process targets at the etch stop layer 544 and exposes the metal lines 534 in the via openings 554 by etching through the etch stop layer 544. Since the wide and narrow metal lines 534 have similar heights, the depths of the via openings 554 are substantially the same and sufficiently exposes the top surfaces of the metal lines 534 therein.

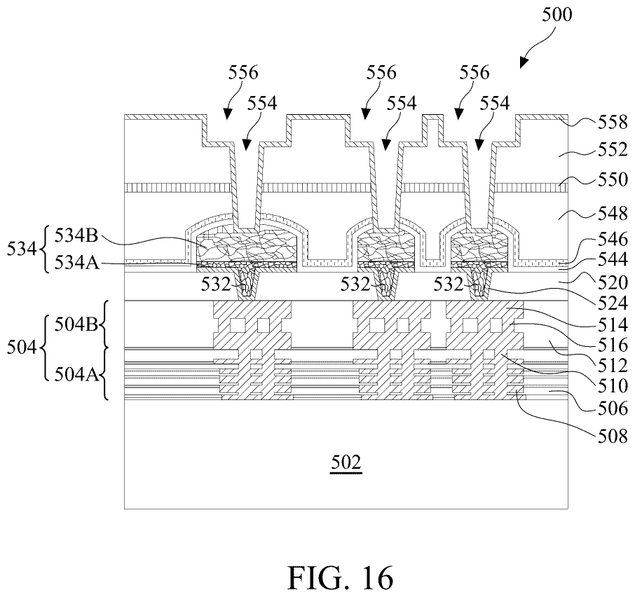

At operation 322, the method 300 (FIG. 5) conformally deposits a seed layer 558 over the device structure 500, such as shown in FIG. 16. The seed layer 558 may be a thin film of a conductive material that aids in the formation of a thicker metallic layer during subsequent processing steps. For example, the seed layer 558 includes a tantalum/copper bilayer, a copper layer, or other suitable metal layer. The seed layer 558 may be deposited by using ALD, CVD, ELD, PVD, or other suitable deposition techniques. In some embodiments, a barrier layer (not shown) is conformally deposited over the device structure 500 prior to the deposition of the seed layer 558. The barrier layer may be formed of a conductive material such as Ta, TaN, TaC, Ti, TIN, TiC, and other suitable material that can block metal element diffusion into the dielectric layer 552, and may be deposited using ALD, CVD, ELD, or PVD, or other suitable deposition techniques. In some implementations, the seed layer 558 is a metal alloy layer containing at least a main metal element, e.g., copper (Cu), and an additive metal element, e.g., manganese (Mn). In one example, the seed layer 558 is a copper-manganese (CuMn) layer. The concentration of the additive metal element may vary in contact structures at different levels in some embodiments. In one example, the seed layers 524 and 558 are both CuMn layers, and the contact structures at a higher level have a higher concentration of manganese than contact structures at a lower level, which is to better mitigate the electro migration without sacrificing the resistivity. That is, the seed layer 558 may have a higher concentration of Mn than the seed layer 524. In another example, the seed layer 558 is a CuMn layer, and the seed layer 524 is a copper layer substantially free of Mn.

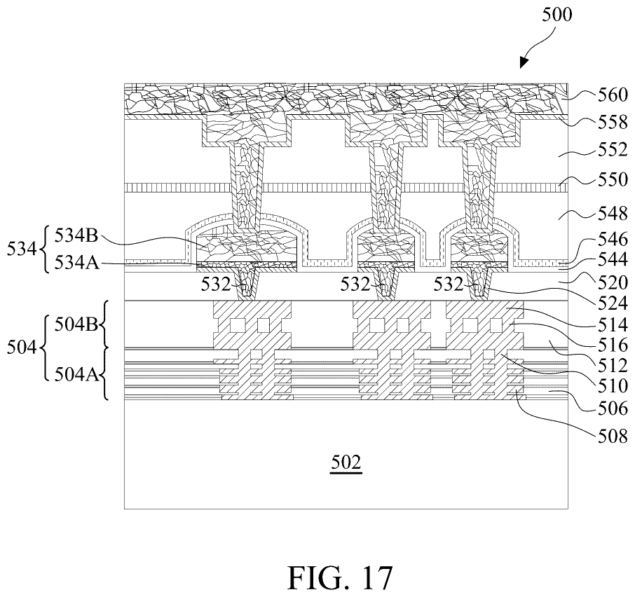

At operation 324, the method 300 (FIG. 5) deposits a conductive material 560 to fill the via openings 554 and the trenches 556, such as shown in FIG. 17. The deposition of the conductive material 560 may include an electroplating process. Unlike the multi-step electroplating process 530 at operations 310 and 312, the electroplating process at operation 324 may use a constant relatively strong current to ensure the copper grain quality and suppress impurities, as the metal line height discrepancy may be less a concern at the bonding pad level. Accordingly, the copper grain size, the surface roughness, and the concentration of impurities in the conductive material 560 may be substantially similar to those of the top portion 534B of the metal lines 534. In some embodiments, the plating current applied at operation 324 is larger than the plating current applied at the second step of the electroplating process 530 at operation 312, and the conductive material 560 may have a larger copper grain size, a smaller surface roughness, and a smaller concentration of impurities than those in the top portion 534B of the metal lines 534.

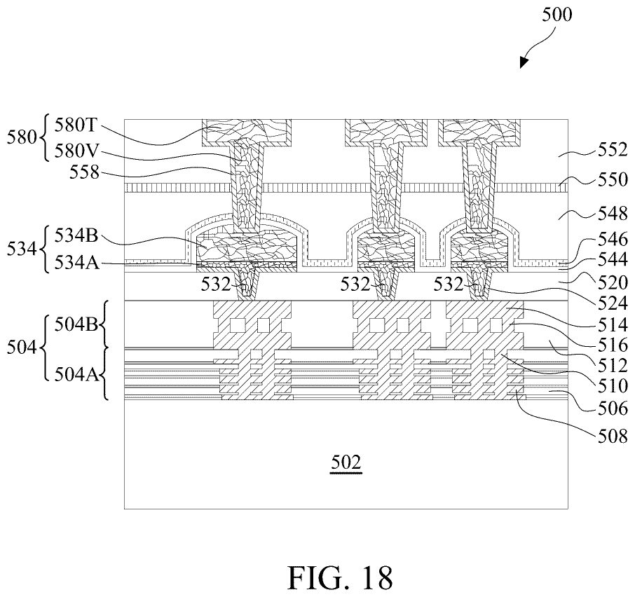

At operation 326, the method 300 (FIG. 5) performs a planarization process such as a CMP process or a mechanical polish process to remove excess portions of conductive material 560 and the seed layer 558, hence forming bonding pad metals (BPM) 580T and bonding pad vias (BPV) 580V. The BPM 580T and BPV 580V collectively define the bonding pads 580, such as shown in FIG. 18. The BPM 580T have electrical connection with the metal lines 534 through the landing of the BPV 580V on the metal lines 534.

The embodiments of this disclosure offer several advantageous features. Through the implementation of a modified electroplating process to create metal lines in an RDL structure, the heights of the metal lines are substantially consistent. This enhancement effectively reduces the occurrence of overlying vias that might otherwise fail to establish sufficient contacts with the narrower metal lines.

In one exemplary aspect, the present disclosure is directed to a method for manufacturing a semiconductor structure. The method includes forming a seed layer on a substrate, forming a photoresist layer on the seed layer, the photoresist layer defining a first opening and a second opening, the first opening being wider than the second opening, performing an electroplating process with a first plating current, thereby growing a bottom portion of a first metal line in the first opening and a bottom portion of a second metal line in the second opening, continuing the electroplating process with a second plating current that is larger than the first plating current, thereby growing a top portion of the first metal line and a top portion of the second metal line, removing the photoresist layer to expose a portion of the seed layer, and removing the exposed portion of the seed layer. In some embodiments, a width of the first metal line is larger than a width of the second metal line, and a height of the first metal line is larger than a height of the second metal line for less than about 0.4 μm. In some embodiments, the bottom portion of the first and second metal lines has a grain size smaller than the top portion of the first and second metal lines. In some embodiments, the bottom portion of the first and second metal lines has a surface roughness larger than the top portion of the first and second metal lines. In some embodiments, the bottom portion of the first and second metal lines has an impurity concentration larger than the top portion of the first and second metal lines. In some embodiments, the first plating current is less than about 0.6 amps per square decimeter (ASD), and the second plating current is larger than about 0.6 ASD. In some embodiments, a ratio of the second plating current and the first plating current ranges from about 2:1 to about 5:1. In some embodiments, the semiconductor structure is immersed in a plating solution during the electroplating process, and the plating solution has a concentration of copper ions less than a concentration of sulfuric acid and a concentration of hydrochloric acid. In some embodiments, a ratio of the concentration of copper ions and the concentration of sulfuric acid ranges from about 1:2 to about 1:4. In some embodiments, a ratio of the concentration of copper ions and the concentration of hydrochloric acid ranges from about 1:2 to about 1:3.8.

In another exemplary aspect, the present disclosure is directed to an electroplating method. The electroplating method includes immersing a semiconductor structure into a plating solution. The plating solution includes copper ions, sulfuric acid, and hydrochloric acid. The plating solution further includes an accelerator, a suppressor, and a leveler. A concentration of the leveler is less than the accelerator and the suppressor. The electroplating method also includes performing an electrochemical reaction on the plating solution to form a redistribution layer on the semiconductor structure. A height difference between metal lines of the redistribution layer is less than about 0.4 μm. In some embodiments, the performing of the electrochemical reaction includes applying a first plating current through the plating solution to form a lower portion of the metal lines, and applying a second plating current through the plating solution to form an upper portion of the metal lines, and the second plating current is different from the first plating current. In some embodiments, the second plating current is stronger than the first plating current. In some embodiments, a grain size of the upper portion of the metal lines is larger than the lower portion of the metal lines. In some embodiments, a ratio of a height of the lower portion of the metal lines and a height of the metal lines ranges from about 10% to about 20%. In some embodiments, the concentration of the leveler is less than each of the accelerator and the suppressor for about 30% to about 50%. In some embodiments, the metal lines of the redistribution layer include a first metal line and a second metal line that is narrower than the first metal line, and a height of the first metal line is larger than the second metal line for less than about 0.3 μm.

In yet another exemplary aspect, the present disclosure is directed to a redistribution structure. The redistribution structure includes a first dielectric layer over a substrate, a first via through the first dielectric layer, a metal line over the first via and in physical contact with the first via, a second dielectric layer over the metal line, and a second via through the second dielectric layer and in physical contact with the metal line. The first via and a bottom portion of the metal line include a conductive material of a first grain size, and a top portion of the metal line and the second via include the conductive material of a second grain size that is different from the first grain size. In some embodiments, the second grain size is larger than the first grain size. In some embodiments, the conductive material is copper.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
an interconnect structure disposed over the substrate, the interconnect structure comprising interconnect layers, each of the interconnect layers comprising metal features disposed in a dielectric layer, a thickness of a bottommost one of the dielectric layers being less than a thickness of at least one of the dielectric layers above the bottommost one of the dielectric layers; and
a redistribution layer disposed over the interconnect structure, the redistribution layer includes a first via in electrical coupling with one of the metal features in the interconnect structure, a first metal line disposed on and in electrical coupling with the first via, a second via in electrical coupling with another one of the metal features in the interconnect structure, and a second metal line disposed on and in electrical coupling with the second via, a width of the first metal line being greater than a width of the second metal line, a thickness of the first metal line equal to a thickness of the second metal line,
wherein each of the first and second metal lines includes a top portion having a conductive material of a first grain size and a bottom portion having the conductive material of a second grain size, and the first grain size is greater than the second grain size.

2. The semiconductor device of claim 1, wherein an interface between the top portion and the bottom portion is substantially flat, and a top surface of the top portion is non-flat.

3. The semiconductor device of claim 1, wherein a thickness of the top portion is greater than a thickness of the bottom portion.

4. The semiconductor device of claim 1, wherein a surface roughness of the top portion is less than a surface roughness of the bottom portion.

5. The semiconductor device of claim 1, wherein an interface between the bottom portion and the top portion in the first metal line and an interface between the bottom portion and the top portion in the second metal line are substantially level.

6. The semiconductor device of claim 1, wherein each of the first and second vias includes the conductive material of the second grain size.

7. The semiconductor device of claim 6, wherein the conductive material extends from the first via to the bottom portion of the first metal line without a discernable interface between the first via and the first metal line.

8. The semiconductor device of claim 1, further comprising:
a seed layer interposing the first and second vias and the interconnect structure, wherein the seed layer interfaces with bottom surfaces of the first and second metal lines.

9. The semiconductor device of claim 1, further comprising:
a third via disposed on and in electrical coupling with the first metal line; and
a bond pad disposed on the third via and in electrical coupling with the third via,
wherein each of the bond pad and the third via includes the conductive material of a third grain size not less than the first grain size.

10. The semiconductor device of claim 9, wherein the third grain size is larger than the first grain size.

11. A semiconductor device, comprising:
an interconnect structure disposed over a substrate, the interconnect structure comprising interconnect layers, each of the interconnect layers comprising metal lines disposed in a dielectric layer, a thickness of a bottommost one of the metal lines being less than a thickness of at least one of the metal lines above the bottommost one of the metal features;
a first dielectric layer over the interconnect structure;
a first via through the first dielectric layer;
a first metal line disposed on the first via and interfacing with the first via;
a second dielectric layer over the first metal line;
a second via through the second dielectric layer and in electrical coupling with the first metal line; and
a bond pad disposed on the second via and interfacing with the second via,
wherein the first via and a bottom portion of the first metal line include a conductive material of a first grain size, and a top portion of the first metal line and the second via include the conductive material of a second grain size that is different from the first grain size.

12. The semiconductor device of claim 11, wherein the second grain size is larger than the first grain size.

13. The semiconductor device of claim 11, wherein the bond pad includes the conductive material of the second grain size.

14. The semiconductor device of claim 11, wherein the conductive material is copper.

15. The semiconductor device of claim 11, wherein a thickness of the bottom portion of the first metal line is less than a thickness of the top portion of the first metal line.

16. The semiconductor device of claim 11, further comprising:
a first seed layer interposing the first via and the interconnect structure; and
a second seed layer interposing the second via and the first metal line.

17. A method, comprising:
forming an interconnect structure over a substrate, the interconnect structure comprising interconnect layers, each of the interconnect layers comprising metal lines disposed in a dielectric layer, a thickness of a bottommost one of the dielectric layers being less than a thickness of at least one of the dielectric layers above the bottommost one of the dielectric layers;
forming a seed layer on the interconnect structure;
forming a patterned layer on the seed layer, the patterned layer including a first opening and a second opening, the first opening being wider than the second opening;
performing an electroplating process with a first plating current, thereby growing a bottom portion of a first metal line in the first opening and a bottom portion of a second metal line in the second opening;
continuing the electroplating process with a second plating current that is different from the first plating current, thereby growing a top portion of the first metal line and a top portion of the second metal line, wherein the top portion of the first metal line and the bottom portion of the first metal line have different grain sizes, wherein the top portion of the second metal line and the bottom portion of the second metal line have different grain sizes;
removing the patterned layer to expose a portion of the seed layer; and
removing the exposed portion of the seed layer.

18. The method of claim 17, wherein a width of the first metal line is larger than a width of the second metal line, and a height of the first metal line is larger than a height of the second metal line for less than about 0.4 μm.

19. The method of claim 17, wherein the first plating current is less than the second plating current.

20. The method of claim 19, wherein a duration of the first plating current is longer than a duration of the second plating current.
